(19) United States
(12) Patent Application Publication
(10) Pub. No.: US 2022/0304197 A1
(43) Pub. Date: Sep. 22, 2022

(54) INFORMATION PROCESSING APPARATUS AND FAN CONTROL METHOD OF INFORMATION PROCESSING APPARATUS

(71) Applicant: HITACHI, LTD., Tokyo (JP)

(72) Inventors: Katsuya AKITOMO, Tokyo (JP); Tsubasa MATSUSHITA, Tokyo (JP); Naoki WADA, Tokyo (JP); Sho IKEDA, Tokyo (JP)

(73) Assignee: HITACHI, LTD., Tokyo (JP)

(21) Appl. No.: 17/469,629

(22) Filed: Sep. 8, 2021

(30) Foreign Application Priority Data
Mar. 22, 2021 (JP) 2021-047711

(51) Int. Cl. H05K 7/20

(52) U.S. Cl. CPC H05K 7/20836; H05K 7/20727

(57) ABSTRACT

When a plurality of fans in a first controller (any of controllers) become activation start objects and a plurality of fans in a second controller (a controller in a predetermined relative positional relationship with the first controller) are positively rotating, the first controller sets a level of a rotational speed of the plurality of fans in the first controller to a first level and the second controller keeps a level of a rotational speed of the plurality of fans in the second controller at a second level that is equal or higher than the first level.

### CROSS-REFERENCE TO PRIOR APPLICATION

This application relates to and claims the benefit of priority from Japanese Patent Application number 2021-47711, filed on Mar. 22, 2021 the entire disclosure of which is incorporated herein by reference.

### BACKGROUND

The present invention generally relates to fan control of an information processing apparatus.

An electronic apparatus disclosed in PTL 1 is known as an example of an information processing apparatus provided with a fan. Examples of the description of PTL 1 include the following.

Fans include an internal fan of a power supply unit and a system fan coupled in parallel to the power supply unit. When the system fan continues to create an airflow in a case where the power supply unit fails, a reverse airflow may be generated around the power supply unit. When the power supply unit is activated after the reverse airflow is generated, the reverse airflow may cause an internal fan of the power supply unit to fail. In consideration thereof, when the power supply unit is activated, the electronic apparatus reduces output of the system fan in order to ensure that the internal fan of the power supply unit operates in a reliable manner.
PTL 1: Japanese Patent Application Laid-open No. 2019-134662

### SUMMARY

An information processing apparatus is known in which a plurality of controllers are arranged inside an enclosure. In order to realize high performance with a limited installation space, a small but high performance information processing apparatus is desirably realized.

In order to realize a small information processing apparatus, a limit is imposed on a size of the enclosure and, consequently, limits are imposed on a pitch between controllers inside the enclosure and a size (a height and an area) of the controllers inside the enclosure.

In order to make such a small information processing apparatus high performance, a plurality of parts are mounted in high density on the controllers and, at the same time, high-performance processors are mounted as processors for information processing.

As described above, in order to realize a small and high-performance information processing apparatus, high cooling performance has to be realized using small fans at each controller.

It is expected that high cooling performance can be realized by providing each controller with a plurality of small fans.

However, in such an information processing apparatus, when a plurality of fans in any of the controllers (hereinafter, “controller of interest” for the sake of convenience) are adopted as activation start objects and a plurality of fans in the controller other than the controller of interest (typically, a controller adjacent to the controller of interest) are positively rotating, both (Problem A) and (Problem B) below occur.

(Problem A) Inside the enclosure, a pitch between controllers is limited. Therefore, a reverse airflow is generated at a fan in the controller of interest. One of the reasons for this is a fan that is positively rotating in the other controller (in other words, one of the reasons being a pressure difference created between the controllers).

(Problem B) In the controller of interest, even if power is supplied to a plurality of fans at the same time, there is no guarantee that activation of the plurality of fans is completed at exactly the same time. In addition, in order to realize a small information processing apparatus, the plurality of fans are provided at high density. Therefore, in the controller of interest, when the activation of a part of the fans is delayed, a reverse airflow is generated at the part of the fans, one of the reasons being fans of which activation has preceded in the controller of interest (in other words, one of the reasons being a pressure difference created in the controller of interest).

Generally, a small fan adopts light-weight blades in order to produce a large air volume (to enable the fan to rotate at high speed with predetermined power). Therefore, when a reverse airflow is generated at a fan of which activation has not been completed, the fan is unable to positively rotate and fails to be activated (for example, reversely rotates).

The technique disclosed in PTL 1 cannot be applied to an information processing apparatus having such problems or, in other words, an information processing apparatus provided with a plurality of controllers which are arranged in an enclosure and which respectively have a plurality of fans. PTL 1 neither discloses nor suggests these unique problems and solutions thereto.

In an information processing apparatus provided with a plurality of controllers which are arranged inside an enclosure and which respectively have a plurality of fans, when a plurality of fans in a first controller (any of the controllers) become activation start objects and a plurality of fans in a second controller (a controller in a predetermined relative positional relationship with the first controller) are positively rotating, the first controller sets a level of a rotational speed of the plurality of fans in the first controller to a first level and the second controller keeps a level of a rotational speed of the plurality of fans in the second controller at a second level that is equal or higher than the first level.

According to the present invention, even when a plurality of fans in any of the controllers become activation start objects while a plurality of fans in another controller are positively rotating, all of the plurality of fans of the controller can be successfully activated while suppressing a decline in cooling performance.

### BRIEF DESCRIPTION OF THE DRAWINGS

FIG. 1 is a diagram showing a configuration of an information processing apparatus according to an embodiment;

FIG. 2 is a schematic view of a cross section obtained by cutting the information processing apparatus along a plane in a front-back direction and an up-down direction;

FIG. 3 is a perspective view of a controller;

FIG. 4 is a plan view of the controller;

FIG. 5 is a schematic view for explaining monitoring between controllers and fan control in each controller;

FIG. 6 is a diagram schematically showing a flow of air at normal time in the information processing apparatus;

FIG. 7 is a diagram schematically showing a reverse airflow in accordance with Problem 1;

FIG. 8 is a diagram schematically showing a reverse airflow in accordance with Problem 2;

FIG. 9 is a graph showing a relationship between pressure received by a fan and a fan activation time;

FIG. 10 is a diagram showing a relationship between a level of fan duty and a pressure difference created between controllers;

FIG. 11 is a diagram showing a configuration of a fan control table;

FIG. 12 is a flow chart showing an example of intra-controller processing performed by an environment microcomputer;

FIG. 13 is a sequence diagram showing a flow of processing between controllers when a failure occurs in a lower controller; and

FIG. 14 is a sequence diagram showing a flow of processing between controllers when the lower controller is mounted.

### DESCRIPTION OF EMBODIMENTS

In the following description, common signs among reference signs may be used when describing elements of the same kind without distinction but reference signs may be used when describing elements of the same kind while distinguishing the elements from one another.

In addition, in the following description, words such as “front”, “back”, “left”, “right”, “up”, and “down” will be used for the sake of convenience as words representing a position or a direction based on an arbitrary position. A position or a direction can also be described using an orthogonal coordinate system (an x axis, a y axis, and a z axis) in a three-dimensional space. A left-right direction can be considered an example of an x-axis direction, a front-back direction can be considered an example of a y-axis direction, and an up-down direction can be considered an example of a z-axis direction.

Furthermore, with respect to the various elements (for example, controllers, fans, and processors) to be described below, the numbers of the elements are not limited to the numbers illustrated in the drawings.

Hereinafter, an embodiment of the present invention will be described. It is to be understood that the embodiment described below is merely an example for describing the present invention and is not intended to limit the scope of the present invention thereto. The present invention can also be implemented in various other modes.

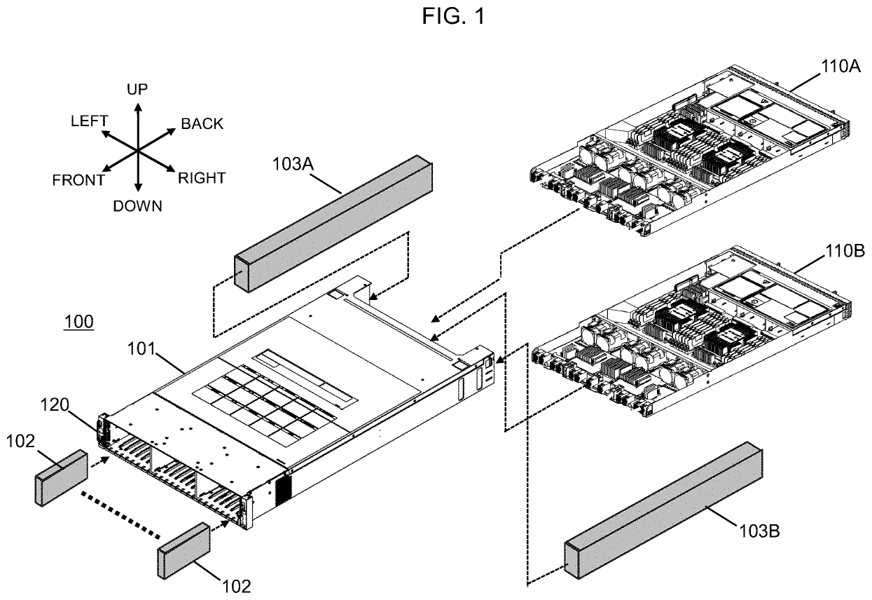

FIG. 1 is a diagram showing a configuration of an information processing apparatus according to the embodiment.

The information processing apparatus 100 is provided with an enclosure 101. The enclosure 101 is a rectangular parallelepiped box with its front face and a back face being respectively opened. For example, the enclosure 101 is longest in the front-back direction, next longest in the left-right direction, and shortest in the up-down direction. For example, a height of the enclosure 101 is 2 U.

A temperature sensor (hereinafter, an inflow air temperature sensor) 120 for detecting a temperature of air that enters from the front face of the enclosure 101 is provided on the front face of the enclosure 101. The temperature detected by the inflow air temperature sensor 120 is used for temperature-based fan control by an environment microcomputer to be described later.

A drive 102 is inserted from the front face of the enclosure 101 to be housed inside the enclosure 101. The drive 102 is a storage device such as an SSD (Solid State Drive) or an HDD (Hard Disk Drive). The drive 102 is oriented vertically and, more specifically, a width of the drive 102 is considered the up-down direction and a height of the drive 102 is considered the left-right direction. The width of the drive 102 is substantially the same as the height of the enclosure 101. In the enclosure 101, a plurality of the drives 102 (for example, a maximum of 24 drives 102) are arranged in the left-right direction. While a single vertical drive array in the left-right direction is constructed in the illustrated example, alternatively, a horizontal drive array in the up-down direction may be constructed and, at the same time, a plurality of horizontal drive arrays may be arranged in the left-right direction. One or more RAIDS (Redundant Arrays of Independent (or Inexpensive) Disks) may be constructed based on the plurality of drives 102.

Power supply units 103A and 103B and controllers 110A and 110B are inserted from a back face of the enclosure 101 to be housed inside the enclosure 101.

The power supply units 103A and 103B are redundant power supply units. In other words, even when a power feed to one of the power supply units 103A and 103B is suspended, by having the remaining power supply unit feed power to the respective elements (for example, the respective controllers 110) inside the information processing apparatus 100, the respective elements can continue operating without experiencing a power outage. The power supply units 103A and 103B are provided at left and right ends inside the enclosure 101. For the sake of convenience, the power supply unit 103A can be referred to as a “left-side power supply unit 103A” and the power supply unit 103B can be referred to as a “right-side power supply unit 103B”. It should be noted that the power supply units 103A and 103B need not necessarily be redundant power supply units and, for example, the power supply unit 103A may function as a power source of a partial element group (for example, including the controller 110A) and the power supply unit 103B may function as a power source of the remaining element group (for example, including the controller 110B).

Each of the controllers 110A and 110B is a device that performs information processing involving providing a logical volume and inputting and outputting data to and from at least one of the plurality of drives 102 in response to an I/O (Input/Output) request designating the logical volume. The controllers 110A and 110B are redundant controllers. In other words, even if one of the controllers 110A and 110B ceases to exist (for example, when suspended due to a failure or the like or detached for maintenance and/or replacement), the remaining controller is capable of continuing information processing (accepting and executing I/O requests and the like). The controllers 110A and 110B are arranged in the up-down direction on a back side inside the enclosure 101. For the sake of convenience, the controller 110A can be referred to as an “upper controller 110A” and the controller 110B can be referred to as a “lower controller 110B”.

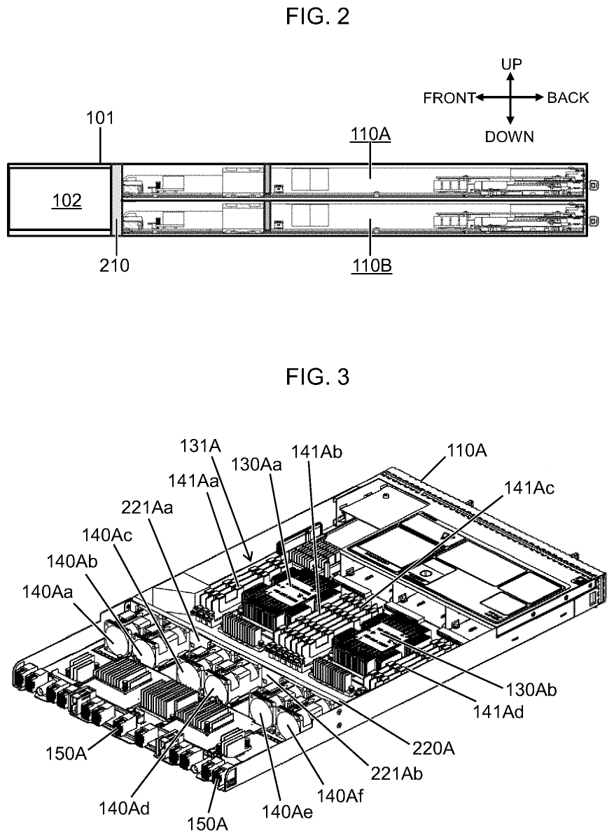

FIG. 2 is a schematic view of a cross section obtained by cutting the information processing apparatus 100 along a plane in the front-back direction and the up-down direction.

A circuit board (hereinafter, a backboard) 210 is provided inside the enclosure 101 so as to partition a space inside the enclosure 101 to a front portion and a back portion. The drive 102 is coupled to a front surface (front) of the backboard 210. The controllers 110A and 110B are coupled to a back surface (rear) of the backboard 210. Each of the controllers 110A and 110B inputs and outputs data to and from the drive 102 via the backboard 210. In addition, the controllers 110A and 110B monitor each other via the backboard 210. The backboard 210 is provided with one or a plurality of through-holes (air holes) that enable air to pass in the front-back direction via the backboard 210.

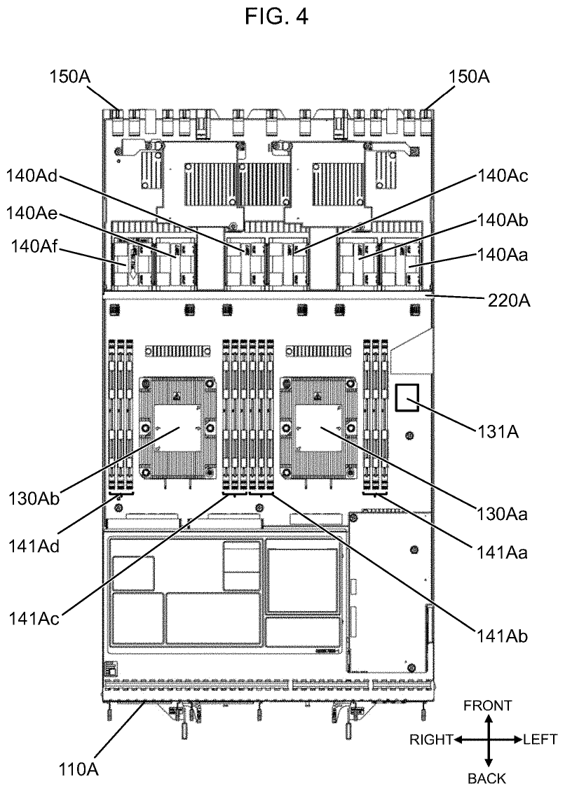

The controllers 110A and 110B share a configuration. Hereinafter, using the controller 110A as an example, the configuration of the controller 110A will be described with reference to FIGS. 3 and 4. It should be noted that, in the description of the present embodiment, reference signs of elements in the controller 110A include “A” and reference signs of elements in the controller 110B include “B” in place of “A”.

FIG. 3 is a perspective view of the controller 110A. FIG. 4 is a plan view of the controller 110A.

The controller 110A has a circuit board, and a plurality of connectors 150A, a plurality of fans 140Aa to 140Af, a fan positioning plate 220A, a plurality of DIMMs (Dual Inline Memory Modules) 141Aa to 141Ad, a plurality of processors 130Aa and 130Ab, and an environment microcomputer 131A are provided on the circuit board.

The plurality of connectors 150A are arranged on a front edge of the controller 110A and are coupled to the back surface of the backboard 210. Only one connector 150A may be provided.

The plurality of fans 140Aa to 140Af are arranged in the left-right direction. In other words, a fan array in the left-right direction is constructed. Each fan 140A is typically an axial flow fan and, by positively rotating, sucks in air from the front and discharges air to the back. While two adjacent sets of the fan 140A are arranged at a regular interval in the example shown in FIGS. 3 and 4, instead of such a configuration, the fans 140Aa to 140Af may be arranged at regular intervals. In addition, fan arrays are not limited to a single array and, for example, a plurality of parallel fan arrays may be arranged in the front-back direction (in this case, a plurality of fans 140A may be arranged in series in the front-back direction).

The fan positioning plate 220A is a plate-like member provided in order to position the fan 140A. For example, the fan positioning plate 220A forms a plurality of openings and an exhaust port of the fan 140A is fixed to an opening. An opening to which the exhaust port of the fan 140A is not fixed is covered by a metal plate 221A. According to the example shown in FIGS. 3 and 4, there are two openings to which the exhaust ports of the fans 140A are not fixed, and the two openings are respectively covered by two metal plates 221Aa and 221Ab. The metal plate 221A is an example of the shielding portion.

The plurality of DIMMs 141Aa to 141Ad and the plurality of processors 130Aa and 130Ab are provided to the back of the plurality of fans 140Aa to 140Af. The DIMM 141A is an example of the memory. For example, the DIMMs 141Aa and 141Ab that are adjacent to the left and right of the processor 130Aa are the DIMMs used by the processor 130Aa, and the DIMMs 141Ac and 141Ad that are adjacent to the left and right of the processor 130Ab are the DIMMs used by the processor 130Ab. Each of the processors 130Aa and 130Ab performs information processing. Each of the processors 130Aa and 130Ab has a temperature sensor that detects a temperature of the processor 130A.

The environment microcomputer 131A is a microcomputer that performs temperature monitoring and fan control. In temperature monitoring, a temperature detected by the inflow air temperature sensor 120 (refer to FIG. 1) and temperatures respectively detected by the temperature sensors of the processors 130Aa and 130Ab are specified. In fan control, rotational speeds of the plurality of fans 140Aa to 140Af are controlled. The environment microcomputer 131A can perform temperature-based fan control that refers to controlling rotational speeds of the plurality of fans based on detected temperatures. The environment microcomputer 131A controls the rotational speeds of the plurality of fans 140Aa to 140Af by PWM (Pulse Width Modulation) control or, more specifically, by duty control. A magnitude of a duty ratio (%) of the fan 140 corresponds to the rotational speed of the fan 140. Hereinafter, the duty ratio of the fan 140 will be referred to as “fan duty”. The higher the fan duty, the higher the rotational speed of the fan 140.

The information processing apparatus 100 is configured such that monitoring is to be performed between the controllers 110 and fan control is to be performed in each controller 110.

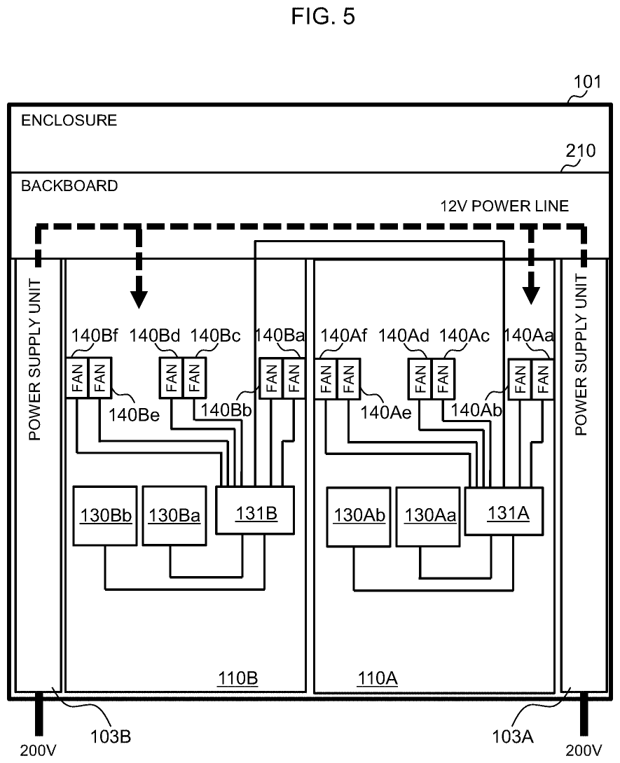

FIG. 5 is a schematic view for explaining the monitoring between the controllers 110 and the fan control in each controller 110.

Power is supplied from each of the power supply units 103A and 103B to each of the controllers 110A and 110B (for example, the fans 140Aa to 140Af and the fans 140Ba to 140Bf).

In each controller 110, the processor 130 and the plurality of fans 140 in the controller 110 are coupled to the environment microcomputer 131. In addition, although not illustrated, the inflow air temperature sensor 120 is coupled to the environment microcomputer 131. The environment microcomputer 131 controls the rotational speeds of the plurality of fans 140 based on temperatures detected by the temperature sensors of the processor 130 (and the temperature detected by the inflow air temperature sensor 120).

In addition, the controllers 110A and 110B coupled to the backboard 210 are configured to monitor each other via the backboard 210. Specifically, an environment microcomputer 131A in the controller 110A and an environment microcomputer 131B in the controller 110B are coupled via the backboard 210 so as to be capable of communicating with each other. Communication is performed between the environment microcomputers 131A and 131B.

Hereinafter, details of the fan control that is performed in the present embodiment will be described.

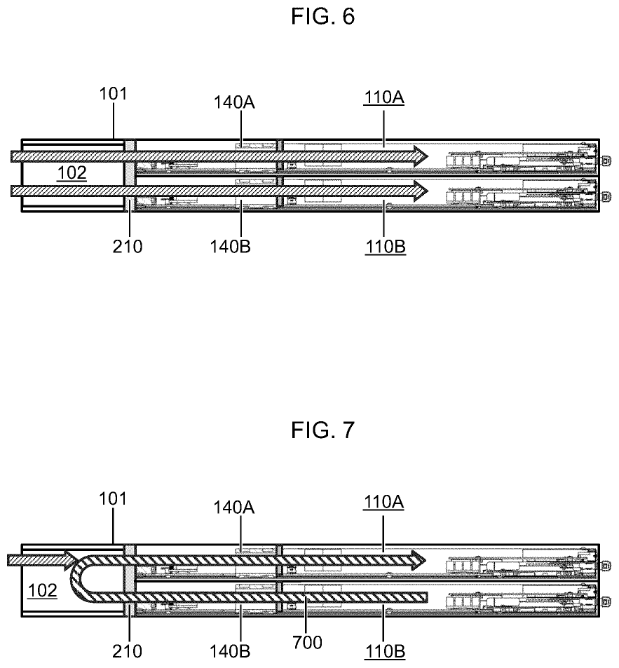

FIG. 6 is a diagram schematically showing a flow of air at normal time in the information processing apparatus 100.

“Normal time” as used herein refers to a time at which all of the fans 140 in each controller 110 are positively rotating. Arrows shown in FIG. 6 schematically indicate a flow of air.

In other words, at normal time, air is sucked in from the front face of the enclosure 101 by the plurality of fans 140A in the upper controller 110A, the sucked air passes through the backboard 210 while cooling the plurality of drives 102, passes through the plurality of fans 140A, and cools the processor 130A to the back of the fans 140A.

In a similar manner, air is sucked in from the front face of the enclosure 101 by the plurality of fans 140B in the lower controller 110B, the sucked air passes through the backboard 210 while cooling the plurality of drives 102, passes through the plurality of fans 140B, and cools the processor 130B to the back of the fans 140B.

In this manner, at normal time, air sucked in by the fan 140A in the upper controller 110A flows on an upper side inside the enclosure 101 toward the back while air sucked in by the fan 140B in the lower controller 110B flows on a lower side inside the enclosure 101 toward the back.

The information processing apparatus 100 is a small and high-performance information processing apparatus. Specifically, since the height of the enclosure 101 is 2 U and the height of each controller 110 is 1 U, the fan 140 mounted to each controller 110 is a small fan. In addition, the processor 130 mounted to each controller 110 is a high-performance processor.

In order to cool a high-performance processor, high cooling performance must be realized using small fans. In the present embodiment, for example, a large air volume is expected from factors (X) and (Y) below and, consequently, high cooling performance is expected.

(X) The fan 140 is provided in plurality in each controller 110. Therefore, cooling is performed by a plurality of fans 140.

(Y) In each controller 110, substantially, air flowing in the controller 110 inevitably passes through the fan 140. This is because there are hardly any gaps above and below the controller 110 and, at the same time, shielding is performed by the metal plate 221 so that air does not flow to the back from the fan 140 without passing through the fan 140. The reason why there are hardly any gaps above and below the controller 110 is that the height of each controller 110 is 1 U as compared to the height of the enclosure 101 being 2U and, at the same time, the height of the fan 140 is the same (substantially the same) height, 1U, as the height of the controller 110.

Let us suppose that, in such an information processing apparatus 100, the plurality of fans 140B in the lower controller 110B become activation start objects while the plurality of fans 140A in the upper controller 110A are positively rotating. In this case, both (Problem 1) and (Problem 2) below occur.

(Problem 1) Refer to FIG. 7. There are hardly any gaps between the controllers 110. Therefore, a reverse airflow 700 is generated at the fan 140B in the lower controller 110B, one of the reasons being the fan 140A that is positively rotating in the upper controller 110A (in other words, one of the reasons being a pressure difference created between the controllers 110).

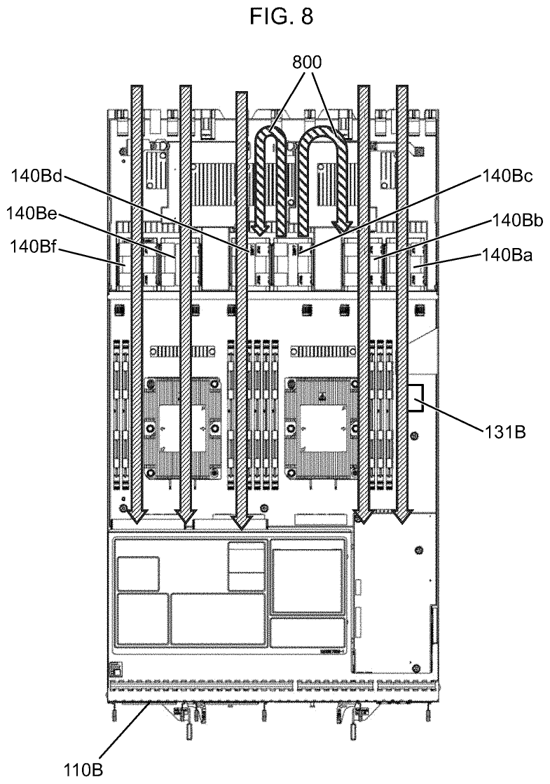

(Problem 2) Refer to FIG. 8. In the lower controller 110B, even if power is supplied to the plurality of fans 140B at the same time, there is no guarantee that activation of the plurality of fans 140B will be completed at exactly the same time. In addition, since the information processing apparatus 100 is small, the plurality of fans 140B are provided at high density. Therefore, in the lower controller 110B, when the activation of the fan 140Bc (an example of a part of the fans) is delayed, a reverse airflow 800 is generated at the fan 140Bc, one of the reasons being other fans 140B (for example, the fans 140Bb and 140Bd adjacent to both sides of the fan 140Bc) of which activation has been completed in advance (in other words, one of the reasons being a pressure difference created in the lower controller 110B).

Generally, a small fan adopted as the fan 140 adopts light-weight blades in order to produce a large air volume. Therefore, when reverse airflows 700 and 800 are generated at the fan 140Bc of which activation has not been completed, there is a risk that the fan 140Bc is unable to positively rotate and fails to be activated (for example, reversely rotates).

The fact that high cooling performance can be expected from factors (X) and (Y) described above means that the possibility of occurrences of (Problem 1) and (Problem 2) described above is not low.

In addition, since the reverse airflow 700 of (Problem 1) and the reverse airflow 800 of (Problem 2) are both caused by a pressure difference, in order to make activation completion of any of the fans 140B successful even when activation completion is delayed, the pressure difference must be reduced. The pressure difference is small when the fan duty in both controllers 110A and 110B is small. Therefore, conceivably, fan duties of both the fan 140A and the fan 140B can be set to a minimum level at activation start of the fan 140B.

However, since the activation start of the fan 140B is a state where only the upper controller 110A among the controllers 110A and 110B is performing cooling, setting the fan duty of the fan 140A to a minimum level causes cooling performance to decline.

In consideration thereof, intensive investigations carried out by the present inventors with respect to causing all of the fans 140B to be successfully activated while suppressing a decline in cooling performance when each fan 140B becomes an activation start object have resulted in the following findings.

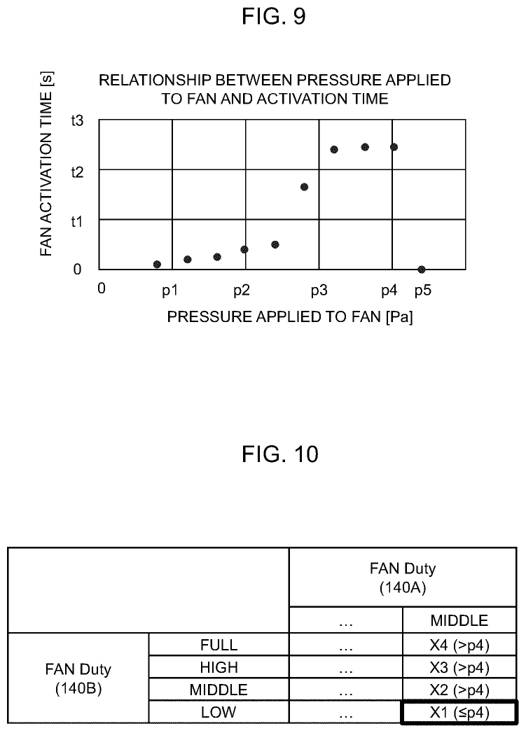

A relationship between pressure received by the fan 140B and an activation time of the fan 140B (time between activation start and activation completion of the fan 140B) is as shown in FIG. 9. According to the relationship shown in FIG. 9, when the pressure received by the fan 140B is p5 that is larger than p4, activation time becomes 0 or, in other words, activation fails. In other words, activation of the fan 140B is successfully completed as long as the pressure received by the fan 140B is equal to or lower than p4.

Therefore, in order to complete activation of all of the fans 140B while suppressing a decline in cooling performance, the levels of the fan duty of the fan 140A in the upper controller 110A is to be set to a maximum level among levels at which a pressure difference of p4 or smaller is created.

A relationship between a level of fan duty and a pressure difference created between controllers 110 is as shown in FIG. 10. “FULL” represents a maximum level and “LOW” represents a minimum level. There may be more or less levels of fan duty than four stages such as “FULL”, “HIGH”, “MIDDLE”, and “LOW”. A “level of fan duty” may represent a range (an upper limit and a lower limit) of fan duty or may correspond to a value of fan duty itself. “X1” to “X4” in FIG. 10 respectively represent pressure differences (in [Pa] units).

Since the level of the fan duty of the fan 140A is preferably as high as possible in order to suppress a decline in cooling performance, pressure differences that are created in accordance with the level of the fan duty of the fan 140B may be compared to p4 described above in a descending order of the level of the fan duty of the fan 140A as follows.

When the level of the fan duty of the fan 140A is “FULL” or “HIGH”, the pressure difference exceeds p4 regardless of the level of the fan duty of the fan 140B.

When the level of the fan duty of the fan 140A is “MIDDLE”, the pressure difference exceeds p4 if the level of the fan duty of the fan 140B is “FULL”, “HIGH”, or “MIDDLE” but the pressure difference equals or falls under p4 if “LOW” as indicated by a bold frame in FIG. 10.

Fan control based on the findings described above is performed in the present embodiment.

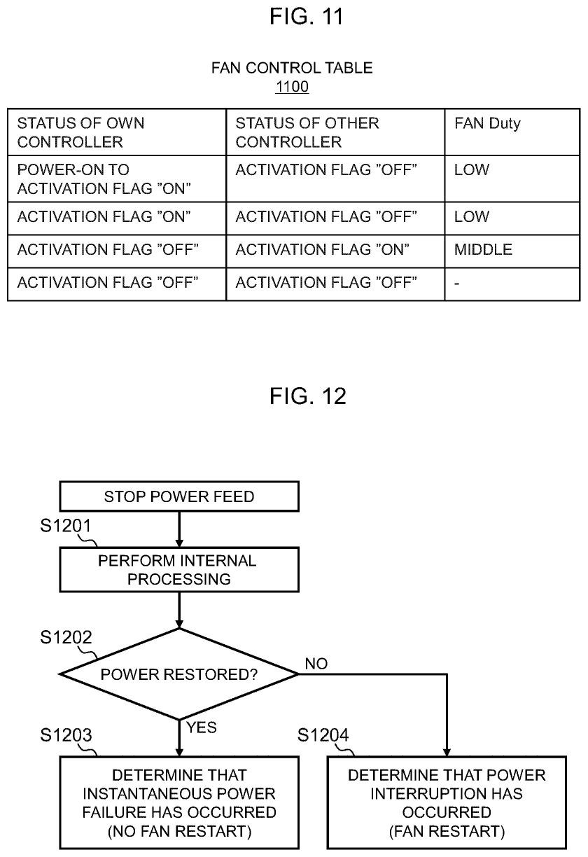

FIG. 11 is a diagram showing a configuration of a fan control table.

A fan control table 1100 is stored in the environment microcomputer 131 of each controller 110. The fan control table 1100 represents a relationship between a combination of a status of an own controller 110 (the controller 110 having the fan control table 1100) and a status of another controller 110 and a level of the fan duty of the fan 140 in the own controller 110. The environment microcomputer 131 performs fan control based on the fan control table 1100. It should be noted that the fan control table 1100 may be stored in a storage area (for example, the DIMM 141) that can be accessed by the environment microcomputer 131 instead of being stored inside the environment microcomputer 131.

In FIG. 11, an “activation flag” represents whether or not the fan 140 is being activated. An activation flag of “ON” signifies that the fan 140 is being activated (activation of the fan 140 has been started but is not yet completed). The fan control table 1100 shown in FIG. 11 reveals the following. When the fan 140 is being activated in the own controller 110, the duty level of the fan 140 in the own controller 110 is considered to be “LOW”.

When the fan 140 is being activated in the other controller 110, the duty level of the fan 140 in the own controller 110 is considered to be “MIDDLE”.

When activation of the fan 140 has been completed ended in both the own controller 110 and the other controller 110, temperature-based fan control is performed. In other words, the duty level of the fan 140 is not fixed and the fan duty is controlled in accordance with a detected temperature.

FIG. 12 is a flow chart showing an example of intra-controller processing performed by the environment microcomputer 131.

For example, when the information processing apparatus 100 has a battery, the environment microcomputer 131 can operate based on power fed from the battery when power feed from the power supply unit 103 is suspended. The processing shown in FIG. 12 is started when the environment microcomputer 131 detects suspension of power feed. The environment microcomputer 131 performs predetermined internal processing (S1201) and determines whether or not power restoration has occurred after the completion of the internal processing (S1202).

When the determination result in S1202 is true (S1202: YES), the environment microcomputer 131 determines that an instantaneous power failure has occurred (S1203). In this case, the environment microcomputer 131 does not restart the fan 140 in the own controller 110 (the controller 110 having the environment microcomputer 131). In addition, the fan control performed when it is determined that an instantaneous power failure has occurred may be temperature-based fan control or the level of the fan duty of the fan 140 in the own controller 110 may be set to a predetermined level (for example, “FULL” or “HIGH”) regardless of the temperature detected by the temperature sensor of each processor 130 or by the inflow air temperature sensor 120.

When the determination result in S1202 is false (S1202: NO), the environment microcomputer 131 determines that a power interruption has occurred (S1204). In this case, the environment microcomputer 131 restarts the fan 140 in the own controller 110.

When the environment microcomputer 131 to perform S1204 is the environment microcomputer 131B of the lower controller 110B and each fan 140A in the upper controller 110A is positively rotating during S1204, pressure differences in accordance with (Problem 1) and (Problem 2) described earlier occur at activation start of each fan 140B of the lower controller 110B. In other words, the fact that S1204 can be performed by the environment microcomputer 131 of each controller 110 is one of the factors that cause (Problem 1) and (Problem 2). Another factor that causes (Problem 1) and (Problem 2) is, for example, a replacement of the controller 110 that is performed for various reasons including a failure of the controller 110.

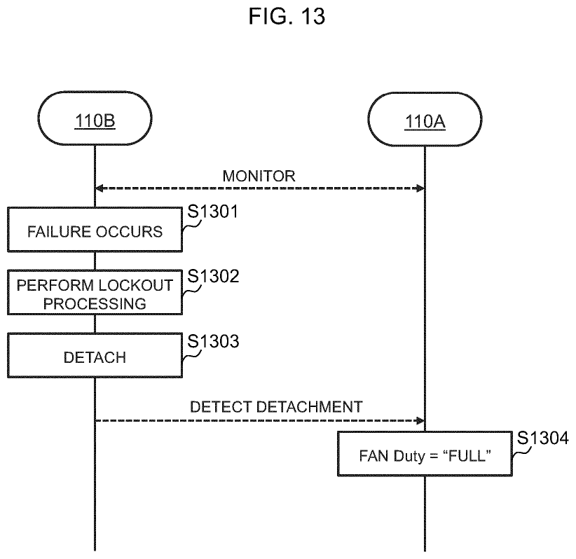

FIG. 13 is a sequence diagram showing a flow of processing between the controllers 110 when a failure occurs in the lower controller 110B.

A failure occurs in the lower controller 110B (S1301), and lockout processing of the lower controller 110B is performed (S1302). Subsequently, the controller 110B is detached from the enclosure 101 (S1303).

In inter-controller monitoring or, in other words, in monitoring performed between controllers 110 (between environment microcomputers 131) via the backboard 210, the controllers 110 detect statuses of each other. The status may include power-on, an activation flag, and a fan duty level.

When the lower controller 110B is detached, in the inter-controller monitoring, the detachment of the lower controller 110B is detected by the upper controller 110A. In this case, the environment microcomputer 131A stops temperature-based fan control in the upper controller 110A and changes the level of the fan duty of the fan 140A to “FULL”. Accordingly, the rotational speed of each fan 140A reaches a maximum speed and a decline in cooling performance of the information processing apparatus 100 is suppressed even when cooling by the lower controller 110B is not performed.

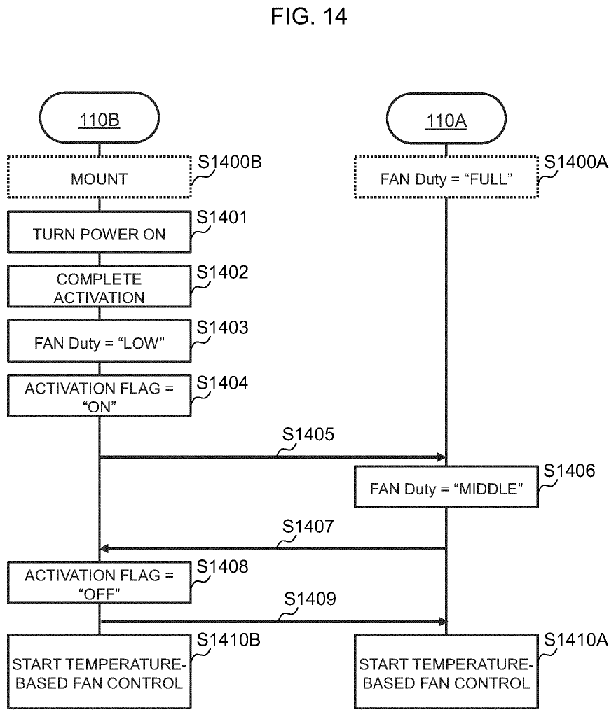

FIG. 14 is a sequence diagram showing a flow of processing between the controllers 110 when the lower controller 110B is mounted.

As indicated in S1304 in FIG. 13, the level of the fan duty of each fan 140A in the upper controller 110A is “FULL” (S1400A). In other words, in the upper controller 110A, each fan 140A is positively rotating at high speed. In this state, the lower controller 110B is to be mounted to the enclosure 101 (coupled to the backboard 210) (S1400B).

When the lower controller 110B is mounted to the enclosure 101, power to the lower controller 110B is turned on (power is supplied to the lower controller 110B from the power supply unit 103) (S1401), and activation of the processor 130B and the environment microcomputer 131B of the lower controller 110B is completed (S1402). At this point, all of the fans 140B in the lower controller 110B become activation start objects.

Therefore, in accordance with the fan control table 1100 (refer to FIG. 11), the environment microcomputer 131B sets the level of the fan duty of the fan 140B to “LOW” (S1403). This is because, from the perspective of the lower controller 110B, the status of its own controller is power-on to activation flag “ON” and the status (as detected in inter-controller monitoring) of another controller is activation flag “OFF”.

After S1403, the environment microcomputer 131B changes the activation flag to “ON” (S1404). In inter-controller monitoring, the activation flag “ON” in the lower controller 110B is conveyed to the environment microcomputer 131A of the upper controller 110A (S1405). Based on the fan control table 1100, the environment microcomputer 131A sets the level of the fan duty of the fan 140A to “MIDDLE” (S1406). This is because, from the perspective of the upper controller 110A, the status of its own controller is activation flag “OFF” and the status of another controller is activation flag “ON”. In inter-controller monitoring, the fact that the level of the fan duty of the fan 140A in the upper controller 110A has been changed to “MIDDLE” is conveyed to the lower controller 110B (S1407).

When the level of the fan duty in the lower controller 110B is “LOW” and the level of the fan duty in the upper controller 110A is “MIDDLE”, since the created pressure difference is equal to or smaller than p4 (refer to FIG. 10), activation of all of the fans 140B is successfully completed (positive rotation is successful) (refer to FIG. 9).

When activation of all of the fans 140B is completed, the environment microcomputer 131B changes the activation flag to “OFF” (S1408). In inter-controller monitoring, the activation flag “OFF” in the lower controller 110B is conveyed to the environment microcomputer 131A of the upper controller 110A (S1409).

After S1408, the environment microcomputer 131B cancels the level of the fan duty of the fan 140B being “LOW” and starts temperature-based fan control (S1410B).

After S1409 (in other words, after the activation flag “OFF” in the lower controller 110B is conveyed to the upper controller 110A), the environment microcomputer 131A cancels the level of the fan duty of the fan 140A being “MIDDLE” and starts temperature-based fan control (S1410A).

This concludes the description of the present embodiment. For example, the description given above can be summarized as follows. The following summary may include supplements to the description given above as well as descriptions of modifications.

The information processing apparatus 100 is provided with an enclosure 101 and a plurality of controllers 110 that are arranged inside the enclosure 101. Each controller 110 is provided with a plurality of fans 140 and a control portion.

Each of the plurality of fans 140 positively rotates to suck in air from the front and discharge air to the back.

The control portion performs temperature-based fan control that refers to controlling rotational speeds of the plurality of fans 140 of which activation has been completed based on a temperature detected with respect to a processor 130. The control portion may include the processor 130 in place of or in addition to an environment microcomputer 131. In other words, while fan control (temperature-based fan control and fan control other than the temperature-based fan control) is performed by the environment microcomputer 131 in the embodiment described above, alternatively, the environment microcomputer 131 may not be provided and fan control may be performed by the processor 130. However, since fan control is performed by a microcomputer that is provided separately from the processor 130 for information processing, a situation where fan control affects performance of the processor 130 with respect to information processing can be avoided.

In addition, while the processor 130 is arranged to the back of the plurality of fans 140 in the embodiment described above, alternatively, the processor 130 may be arranged to the front of the plurality of fans 140 in place of or in addition to being arranged to the back of the plurality of fans 140.

When the plurality of fans 140B in the lower controller 110B become activation start objects and the plurality of fans 140A in the upper controller 110A are positively rotating, the following takes place.

(a) The environment microcomputer 131B sets a level of a rotational speed of the plurality of fans 140B to a first level.

(b) The environment microcomputer 131A of the upper controller 110A keeps a level of a rotational speed of the plurality of fans 140A at a second level that is equal or higher than the first level.

Accordingly, even when the plurality of fans 140B in the lower controller 110B become activation start objects while the plurality of fans 140A in the upper controller 110A are positively rotating, based on the fact that temperature conditions differ between the lower controller 110B in which the fan 140B is about to be activated and the upper controller 110A in which activation of the fan 140A has already been completed, all of the fans 140B in the lower controller 110B can be successfully activated while suppressing a decline in the cooling performance of the upper controller 110A.

While “LOW” in the lower controller 110B represents an example of a first level and “MIDDLE” in the upper controller 110A represents an example of a second level in the embodiment described above, there may be cases where the level of the lower controller 110B being the same “MIDDLE” level as the upper controller 110A represents an example of the first level. Specifically, depending on a distance between the controllers 110 and the fan adopted as the fan 140, as long as a pressure difference is equal to or smaller than p4 (refer to FIG. 9) described above even though levels of fan duties of both controllers 110A and 110B are “MIDDLE”, the level of the fan duty of the fan 140B during activation may be “MIDDLE” in both controllers 110A and 110B. However, even if the fan 140B is successfully activated, since the smaller the pressure difference, the shorter the activation time (refer to FIG. 9), the first level is preferably lower than the second level. To put it another way, depending on which of fan activation time and cooling performance is to be prioritized, the control portion (for example, the environment microcomputer 131) may control the first level to be as high as possible or as low as possible within a range equal to or lower than the second level.

In addition, the lower controller 110B represents an example of the first controller (any of the controllers). The upper controller 110A represents an example of the second controller (a controller in a predetermined relative positional relationship with the first controller). In the embodiment described above, since the information processing apparatus 100 is provided with two controllers 110, one of the controllers 110A and 110B is the first controller and the other of the controllers 110A and 110B is the second controller, alternatively, the information processing apparatus 100 may be provided with three or more controllers, and when one of the controllers is the first controller, each of one or more controllers (for example, one or more controller present within a certain distance from the first controller) among the remaining two or more controllers may be the second controller.

The environment microcomputer 131A of the upper controller 110A may set a level of a rotational speed of the plurality of fans 140A at a third level that is equal or higher than the second level when rotation of the plurality of fans 140B in the lower controller 110B stops. Accordingly, a decline in the cooling performance of the information processing apparatus 100 can be suppressed. This is particularly useful with respect to cooling of the plurality of drives 102 which are common cooling objects of the controllers 110A and 110B inside the enclosure 101. While the drives 102 are provided to the front of the controllers 110A and 110B, alternatively, the drives 102 may be provided to the back of the controllers 110A and 110B in place of or in addition to being provided to the front of the controllers 110A and 110B. The plurality of drives 102 are an example of a cooling object which is common to the plurality of controllers and which is provided in at least one of the front and the back of the plurality of controllers.

In the enclosure 101, monitoring may be performed between the controllers 110. The “monitoring” may be an example of communication. The communication between the controllers 110 may be transmission and reception of information or read and write of information by one controller 110 with respect to information in a DIMM of another controller 110. The environment microcomputer 131A of the upper controller 110A may detect that, while communicating with the lower controller 110B, the plurality of fans 140B in the lower controller 110B have become activation start objects (for example, an activation flag of “ON”) and set the level of the rotational speed of the fan 140A to the second level. In this manner, by having the upper controller 110A control the fan 140A of the own controller 110A while monitoring a status of the fan 140B of the lower controller 110B, the fan 140B of the other controller 110B can be successfully activated. In other words, the fan 140B of the other controller 110B can be successfully activated while suppressing a decline in cooling performance in not only the own controller 110A (own system) but in the entire information processing apparatus 100 including the other controller 110B (another system).

In this case, since each controller 110 performs temperature-based fan control based on a temperature detected with respect to the processor 130 in the controller 110 (in other words, individual temperature-based fan control), each controller 110 may be considered a single system. In the embodiment described above, temperature-based fan control may be started when all of the fans 140B positively rotate at a rotational speed of “LOW” (an example of the first level) after the environment microcomputer 131B of the lower controller 110B sets the rotational speed of the fans 140B to “LOW”. On the other hand, temperature-based fan control may be started when the activation flag “OFF” is detected in the lower controller 110B after the environment microcomputer 131A of the upper controller 110A sets the rotational speed of the fan 140A to “MIDDLE” (an example of the second level).

Each controller 110 may be provided with a shielding portion that shields at least one of (p) and (q) below.

(p) In a first range which extends in an arrangement direction of the plurality of fans 140 and which includes exhaust ports of the respective fans 140, at least a part of openings other than the exhaust ports.

(q) In a second range which extends in the arrangement direction of the plurality of fans 140 and which includes intake ports of the respective fans 140, at least a part of openings other than the intake ports.

Both the first range and the second range may be planes defined by the arrangement direction of the plurality of fans 140 and a height direction of the controller 110. In the first range, all of the opening portions other than the exhaust ports may be shielded by the shielding portion, and in the second range, all of the opening portions other than the intake ports may be shielded by the shielding portion. Accordingly, air can be prevented from flowing to the back of the fan 140 by passing locations other than the fan 140 and, therefore, the air volume from the fan 140 toward the back can be increased.

In the embodiment described above, among a fan positioning plate 200 which extends in the arrangement direction of the plurality of fans 140 and which includes openings to which the exhaust ports of the respective fans 140 are to be set, openings other than the openings to which the exhaust ports are set are to be shielded by a metal plate 221 (an example of the shielding portion). Another fan positioning plate may be prepared which extends in the arrangement direction of the plurality of fans 140 and which includes openings to which the intake ports of the respective fans 140 are to be set, and openings other than the openings to which the intake ports are set may be shielded by a metal plate.

For example, in the first range (or the second range) described above, opening portions other than the exhaust ports (or the intake ports) are created by constructing fan groups in which M-number of (where M is an integer equal to or larger than 2) fans 140 are arranged adjacent in parallel to each other and lining up a plurality of the fan groups so as to be separated from each other (in the embodiment described above, M=2). Given that there are height restrictions, a location of the circuit board where the fan 140 is to be mounted may be a cutout and the fan 140 may be placed in the cutout. While signal lines and power lines are passed through a surface layer and/or an inner layer of the board between one fan 140 and another fan 140, power lines have a risk of burnout if a wiring width is too narrow with respect to a current and signal lines have a risk of incurring too much loss to the extent that reception becomes impossible if routing distance is too long. Therefore, by lining up fan groups, each constituted by M-number of fans being arranged adjacent in parallel to each other, so as to be separated from each other, a wiring area which has a certain width and which prevents routing from being too circuitous can be secured.

The height of each controller 110 is 1 U, and the height of each fan 140 in the controller 110 may be the same (substantially the same) as the height of the controller 110 (this may refer to a state where the fan 140 is placed on a circuit board of the controller or a state where the fan 140 is embedded in a location where the board has been cut out). Such a configuration enables substantially all of the air that flows in the controller 110 to pass through the fan 140 and, accordingly, increases the volume of air that flows through the fan 140. As a consequence, an effect of reverse airflows in accordance with (Problem 1) and (Problem 2) described earlier is large. However, as described above, in the present embodiment, all of the fans 140B can be successfully activated while suppressing a decline in cooling performance.

We claim:

1. An information processing apparatus, comprising:
an enclosure; and
a plurality of controllers arranged inside the enclosure, wherein
each of the plurality of controllers includes:
a plurality of fans which respectively suck in air from the front and discharge the air to the back by positively rotating; and
a control portion which includes a processor for information processing that is arranged in at least one of the front and the back of the plurality of fans, and which performs temperature-based fan control, which is control on a rotational speed of the plurality of fans, of which activation has been completed, based on a temperature having been detected with respect to the processor, and
when a plurality of fans in a first controller that is any of the controllers have become activation start objects and a plurality of fans in a second controller that is in a predetermined relative positional relationship with the first controller are positively rotating:
(a) the control portion of the first controller sets a level of a rotational speed of the plurality of fans in the first controller to a first level; and
(b) the control portion of the second controller keeps a level of a rotational speed of the plurality of fans in the second controller at a second level that is equal or higher than the first level.

2. The information processing apparatus according to claim 1, wherein
the control portion of the second controller sets a level of a rotational speed of the plurality of fans in the second controller to a third level that higher than the second level when rotation of the plurality of fans in the first controller stops.

3. The information processing apparatus according to claim 2, comprising,
in the enclosure, a cooling object which is common to the plurality of controllers and provided in at least one of the front and the back of the plurality of arranged controllers.

4. The information processing apparatus according to claim 1, wherein
in the enclosure, the second controller is configured to communicate with the first controller, and
the control portion of the second controller performs the (b) upon detecting, in the communication with the first controller, that the plurality of fans in the first controller have become activation start objects.

5. The information processing apparatus according to claim 4, wherein
when the control portion of the second controller detects, in the communication with the first controller, that rotation of the plurality of fans in the first controllers stops, the control portion of the second controller sets a level of a rotational speed of the plurality of fans in the second controller to a third level that is higher than the second level.

6. The information processing apparatus according to claim 4, wherein
the control portion of the first controller starts temperature-based fan control when, after the (a), all of the plurality of fans having become activation start objects in the first controller positively rotate at a rotational speed of the first level, and
the control portion of the second controller starts temperature-based fan control when, after the (b), the control portion of the second controller detects, in communication with the first controller, that all of the plurality of fans having become activation start objects in the first controller are positively rotating at a rotational speed of the first level.

7. The information processing apparatus according to claim 1, wherein
in each of the controllers, the control portion includes, in addition to the processor, a fan control portion for controlling a rotational speed of the plurality of fans in the controller,
the fan control portion of each of the controllers performs temperature-based fan control with respect to the controller, and
when the plurality of fans in the first controller become activation start objects,
the fan control portion of the first controller performs the (a) and
the fan control portion of the second controller performs the (b).

8. The information processing apparatus according to claim 1, wherein
each of the controllers includes a shielding portion which shields at least one of (p) and (q) below:
(p) in a first range which extends in an arrangement direction of the plurality of fans and which includes exhaust ports of the respective fans, at least a part of openings other than the exhaust ports; and
(q) in a second range which extends in the arrangement direction of the plurality of fans and which includes intake ports of the respective fans, at least a part of openings other than the intake ports.

9. The information processing apparatus according to claim 8, wherein
in each of the controllers,
a height of the controller is 1 U, and
a height of each fan in the controller is the same as the height of the controller.

10. A fan control method of an information processing apparatus including a plurality of controllers arranged inside an enclosure,
each of the plurality of controllers including: a plurality of fans which respectively suck in air from the front and discharge the air to the back by positively rotating; and a processor for information processing that is arranged in at least one of the front and the back of the plurality of fans,
the fan control method comprising:
when a plurality of fans in a first controller that is any of the controllers have become activation start objects and a plurality of fans in a second controller in a predetermined relative positional relationship with the first controller are positively rotating:
(a) setting a level of a rotational speed of the plurality of fans in the first controller to a first level; and
(b) keeping a level of a rotational speed of the plurality of fans in the second controller at a second level that is equal or higher than the first level.
